(19) United States
(12) Patent Application Publication
(10) Pub. No.: US 2006/0138474 A1
(43) Pub. Date: Jun. 29, 2006

(54) Recess gate and method for fabricating semiconductor device with the same

(76) Inventors: Jae-Seon Yu, Kyoungki-do (KR); Phil-Goo Kong, Kyoungki-do (KR)

Correspondence Address: BLAKELY SOKOLOFF TAYLOR & ZAFMAN, 12400 WILSHIRE BOULEVARD, SEVENTH FLOOR, LOS ANGELES, CA, 90025-1030, US

(21) Appl. No.: 11/181,626

(22) Filed: Jul. 13, 2005

(30) Foreign Application Priority Data
Dec. 29, 2004 (KR) 2004-0115061

(51) Int. Cl. H01L 31/112

(52) U.S. Cl. 257/268

(57) ABSTRACT

A recess gate and a method for fabricating a semiconductor device with the same are provided. The recess gate includes: a substrate; a recess formed with a predetermined depth in a predetermined portion of the substrate; a gate insulation layer formed over the substrate with the recess; a gate polysilicon layer formed on the gate insulation layer; a gate metal layer being formed on the gate polysilicon layer and filling the recess; and a gate hard mask formed on the gate metal layer.

### FIELD OF THE INVENTION

The present invention relates to a semiconductor technology; and, more particularly, to a recess gate and a method for fabricating a semiconductor device with the same.

### DESCRIPTION OF RELATED ARTS

Gate lines are usually formed on planarized active regions. However, as the size of a pattern has been decreased, a channel length of a gate has been decreased and a doping concentration of an ion implantation has been increased, thereby resulting in an increase in an electric field, which causes junction leakage. Thus, the above gate line formation has a difficulty in securing a refresh characteristic.

As for an improved gate line formation method, a recess gate formation process of forming a gate after recessing a portion of an active region has been suggested. The recess gate formation process makes it possible to increase the channel length and decrease the doping concentration of the ion implantation. Thus, through this recess gate formation process, the refresh characteristic has been improved.

FIGS. 1A to 1C are cross-sectional views of recess gates for illustrating a conventional method for forming the same.

Referring to FIG. 1A, portions of a silicon substrate 11 are recessed until reaching a predetermined depth, thereby obtaining a plurality of recesses 12.

Then, as shown in FIG. 1B, a gate insulation layer 13 is formed over a surface of the silicon substrate 11. A gate polysiliocn layer 14 is formed on the gate insulation layer 13 until the gate polysilicon layer 14 fills the recesses 12. A gate metal layer 15 and a gate hard mask layer 16 are sequentially formed on the gate polysilicon layer 14. The gate metal layer 15 is based on a material such as tungsten silicide or tungsten to reduce sheet resistance of recess gates. The gate hard mask layer 16 is formed by using silicon nitride.

Referring to FIG. 1C, the gate hard mask layer 16, the gate metal layer 15 and the gate polysilicon layer 14 are patterned through a gate patterning process to form a plurality of recess gates 100. Herein, reference numerals 14A, 15A and 16A represent a patterned gate polysilicon layer, a patterned gate metal layer and a gate hard mask, respectively.

According to the above recess gate formation method, when the gate polysilicon layer 14 fills the recesses 12, it is difficult to fill the gate polysilicon layer 14 into recesses 12 without generating voids because of an aspect ratio of the recesses.

If a thickness of the gate polysilicon layer 14 is increased to solve the problem of the void generation, a height of the individual recess gate 100 increases, thereby resulting in another difficulty in etching an oxide layer used for isolating contact plugs, which will be formed through a subsequent process.

FIG. 1D is a cross-sectional view of a conventional plug isolation oxide layer for illustrating an incidence of etch-stop. It should be noted that the same reference numerals are used for the same configuration elements described in FIGS. 1A to 1C.

As shown, a gate spacer layer 17 based on silicon nitride is formed on the silicon substrate 11 and on the recesses gates 100 and then, an inter-layer insulation layer 18 for isolating plugs is formed on the gate spacer layer 17. Afterwards, the inter-layer insulation layer 18 is subjected to a self-aligned contact etching process to form a contact hole 19 opening a surface of the silicon substrate 11 disposed between the recess gates 100. However, as illustrated in FIG. 1D, since the recess gates 100 are too high, a thickness of the inter-layer insulation layer 18 to be etched for forming the contact hole 19 increases. As a result, there may be a problem in that the contact hole 19 is not completely opened.

### SUMMARY OF THE INVENTION

It is, therefore, an object of the present invention to provide a recess gate whose height is reduced without generating voids when a gate electrode material is filled into a recess and a method for fabricating the same.

In accordance with an aspect of the present invention, there is provided a recess gate of a semiconductor device, including: a substrate; a recess formed with a predetermined depth in a predetermined portion of the substrate; a gate insulation layer formed over the substrate with the recess; a gate polysilicon layer formed on the gate insulation layer; a gate metal layer formed on the gate polysilicon layer and filling the recess; and a gate hard mask formed on the gate metal layer.

In accordance with another aspect of the present invention, there is provided a method for fabricating a semiconductor device, including the steps of: forming a recess by etching a substrate to a predetermined depth; forming a gate insulation layer over the substrate including the recess; forming a gate polysilicon layer on the gate insulation layer; forming a gate metal layer on the gate polysilicon layer such that the gate metal layer fills the recess; forming a gate hard mask layer on the gate metal layer; and sequentially etching the gate hard mask layer, the gate metal layer and the gate polysilicon layer to form a recess gate whose bottom portion is filled into the recess.

### BRIEF DESCRIPTION OF THE DRAWINGS

The above and other objects and features of the present invention will become better understood with respect to the following description of the preferred embodiments given in conjunction with the accompanying drawings, in which:

FIGS. 1A to 1C are cross-sectional views of recess gates for illustrating a conventional method for fabricating the same;

FIG. 1D is a cross-sectional view of a conventional plug isolation oxide layer for illustrating an incidence of etch-stop;

FIG. 2 is a cross-sectional view showing a semiconductor device with recess gates in accordance with a preferred embodiment of the present invention;

FIGS. 3A to 3E are cross-sectional views illustrating a method for fabricating recess gates in accordance with the preferred embodiment of the present invention; and

FIG. 4 is a cross-sectional view illustrating a method for forming contact holes in a semiconductor device to which recess gates fabricated according to the preferred embodiment of the present invention are applied.

### DETAILED DESCRIPTION OF THE INVENTION

A recess gate and a method for fabricating a semiconductor device with the same in accordance with a preferred embodiment of the present invention will be described in detail with reference to the accompanying drawings.

FIG. 2 is a cross-sectional view showing a semiconductor device with recess gates in accordance with a preferred embodiment of the present invention.

As shown, each of the recess gates 200 includes: a substrate 21 based on a material such as silicon; a recess 25 formed with a predetermined depth in a portion of the substrate 21; a gate insulation layer 26 formed on the recess 25 and on the substrate 21; a patterned gate polysilicon layer 27A formed on the gate insulation layer 26; a patterned gate metal layer 28A being formed on the patterned gate polysilicon layer 27A and filling the recess 25; and a gate hard mask 29A formed on the patterned gate metal layer 28A.

In FIG. 2, the patterned gate polysiliocn layer 27A is obtained by patterning a gate polysilicon layer, which is formed thinly on the gate insulation layer 26 along a profile of the recess 25. The patterned gate metal layer 28A is obtained by patterning a gate metal layer, which is formed on the gate polysilicon layer such that the gate metal layer is in a wide contact with the gate polysiliocn layer and fills the recess 25. The formation of the patterned gate polysilicon layer 27A and the patterned gate metal layer 28A will be described in detail below.

Since the patterned gate polysilicon layer 27A and the patterned gate metal layer 28A are formed thinly, a height of the individual recess gate 200 is reduced. Also, although the patterned gate polysilicon layer 27A and the patterned gate metal layer 28A are formed thinly, it is still possible to decrease line resistance of the individual recess gate 200 since the gate metal layer is formed to have a wide contact with the gate polysilicon layer.

The patterned gate metal layer 28A is formed by using a material selected from a group consisting of tungsten silicide, tungsten, cobalt silicide and titanium silicide and has a thickness ranging from approximately 500 Å to approximately 1,500 Å. The patterned gate polysilicon layer has a thickness ranging from approximately 100 Å to approximately 1,000 Å. Also, the recess 25 is formed to have a rounded edge shape.

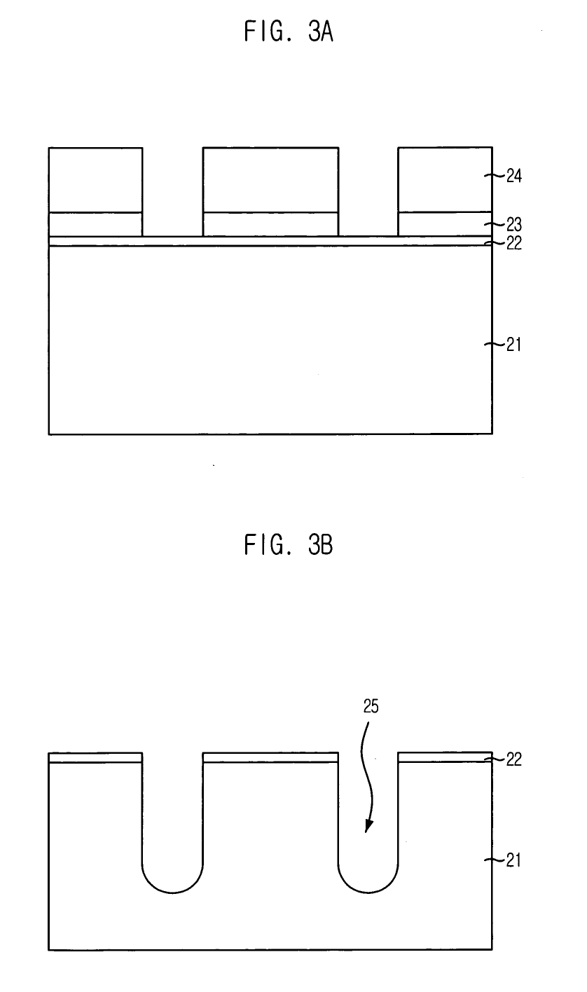

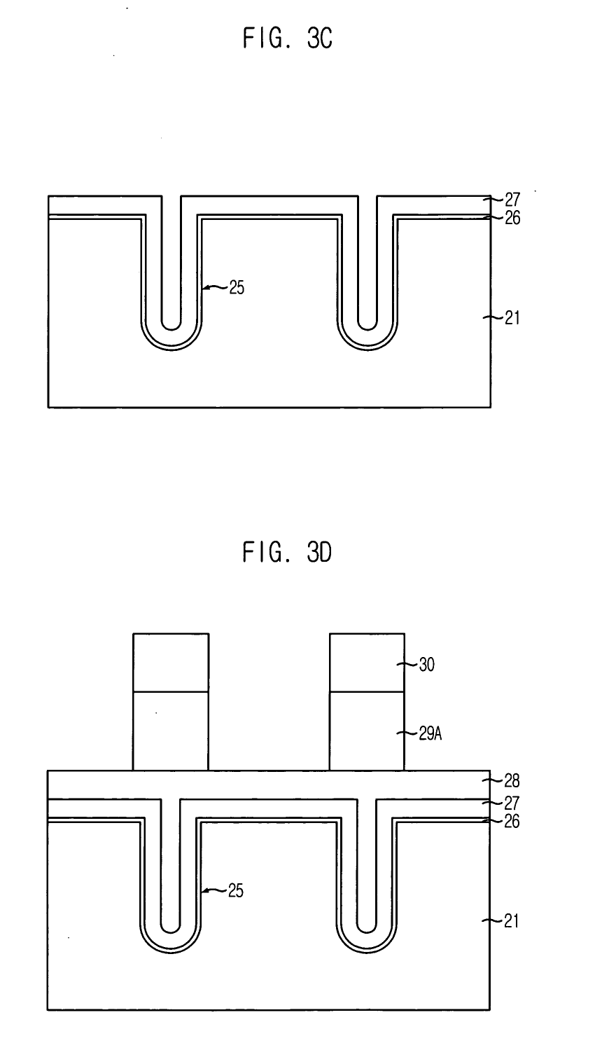

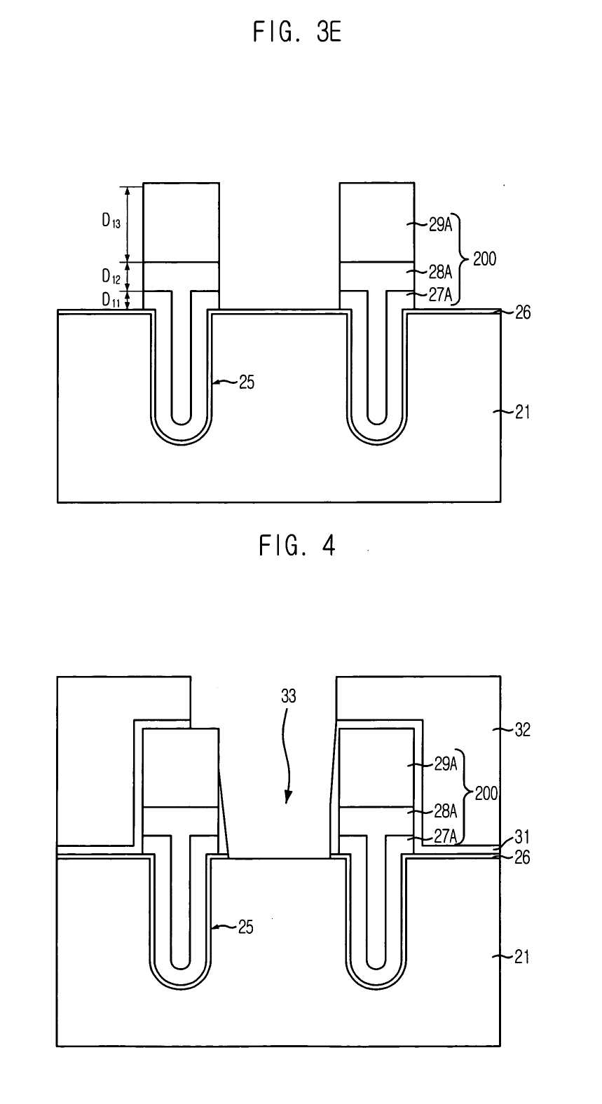

FIGS. 3A to 3E are cross-sectional views illustrating a method for forming a semiconductor device with recess gates in accordance with the preferred embodiment of the present invention. Herein, the same reference numerals are used for the same configuration elements described in FIG. 2.

Referring to FIG. 3A, a pad oxide layer 22 and a hard mask polysilicon layer 23 are sequentially formed on a substrate 21. Herein, the pad oxide layer 22 is a typical pad oxide layer used during a shallow trench isolation (STI) process, which is not illustrated in this drawing though. Generally, the pad oxide layer is used as a device isolation layer formed through the STI process. Also, the hard mask polysilicon layer 23 acts as an etch barrier when the substrate 21 is etched to form recesses and has a thickness ranging from approximately 1,000 Å to approximately 5,000 Å.

Although not illustrated, a photosensitive layer is formed on the hard mask polysilicon layer 23 and patterned through a photo-exposure and developing process, thereby forming a mask pattern 24. By using the mask pattern 24 as an etch barrier, the hard mask polysilicon layer 23 is etched.

Referring to FIG. 3B, the mask pattern 24 is removed through a strip process and afterwards, the pad oxide layer 22 is etched by using the etched hard mask polysilicon layer 23 as an etch barrier. Portions of the substrate 21 exposed by the pad oxide layer 22 are etched until reaching a predetermined depth, thereby obtaining a plurality of recesses 25. At this time, during this etching process for forming the recesses 25, the hard mask polysilicon layer 23 is used up since the hard mask polysilicon layer 23 is based on the same material for the substrate 21, that is, silicon.

Particularly, the above etching process for forming the recesses 25 is carried out at an etch apparatus in which inductively coupled plasma (ICP), decoupled plasma source (DPS), electron cyclotron resonance (ECR), or magnetically enhanced reactive ion etch (MERIE) is used. At this time, a mixed gas of chlorine (Cl₂), oxygen (O₂), hydrogen bromide (HBr) and argon (Ar) is used as an etch gas. The Cl₂ gas, the HBr gas, and the Ar gas are flowed individually in an amount ranging from approximately 10 sccm to approximately 100 sccm, while the O₂ gas is flowed in an amount ranging from approximately 1 sccm to approximately 20 sccm. Approximately 50 W to approximately 400 W of a bottom power is supplied, and a pressure is set to be in a range from approximately 5 mtorr to approximately 50 mtorr.

Since the recesses 25 have sharply angled edges after the above etching process, an additional light-etch treatment is performed by using a carbon fluoride (CF) and O₂ containing plasma to round the sharply angled edges of the recesses 25. The light-etch treatment additionally provides an effect of alleviating damages on the substrate 21 caused by the plasma during the etching process for forming the recesses 25. Also, the light-etch treatment results in a reduced generation of horns at boundary regions between the device isolation regions and the recesses 25.

Referring to FIG. 3C, the pad oxide layer 22 is removed y using a solution of fluoric acid (HF) or a solution of buffered oxide etchant (BOE) obtained as mixing ammonium fluoride (NH₄F), hydrogen peroxide (H₂O₂) and water (H₂O). Afterwards, a gate insulation layer 26 is formed on the substrate 21 and on the recesses 25 and then, a gate polysilicon layer 27 is formed thinly on the gate insulation layer 26 along the profile of the recesses 25. Especially, instead of filling the recesses 25, the gate polysilicon layer 27 is formed over the recesses 25, and particularly, a thickness of the gate polysilicon layer 27 ranges from approximately 100 Å to approximately 1,000 Å.

Referring to FIG. 3D, a gate metal layer 28 is formed on the gate polysilicon layer 27 until the gate metal layer 28 fills the recesses 25 and then, gate hard masks 29A are formed on the gate metal layer 28. At this time, the gate metal layer 28 is formed in a thickness that is enough to be filled into the recesses 25, so that the gate metal layer 28 is in a wide contact with the gate polysilicon layer 27 even though the gate metal layer 28 is thinly formed. As a result of this wide contact, it is possible to reduce line resistance of targeted recess gates. Preferably, the thickness of the gate metal layer 28 is in a range from approximately 500 Å to approximately 1,500 Å. Also, the gate hard metal layer 28 is formed by using a material selected from a group consisting of tungsten silicide, tungsten, cobalt silicide and titanium silicide. The gate hard masks 29A are formed by using silicon nitride (Si₃N₄).

In more detail of the formation of the gate hard masks 29A, although not illustrated, a photosensitive layer is formed on a gate hard mask layer and then patterned through a photo-exposure and developing process, thereby obtaining a gate mask pattern 30. Afterwards, the gate hard mask layer is etched by using the gate mask pattern 30 as an etch barrier, thereby obtaining the gate hard masks 29A.

Referring to FIG. 3E, the gate mask pattern 30 is removed, and afterwards, the gate metal layer 28 and the gate polysilicon layer 27 are sequentially etched with use of the gate hard masks 29A as an etch barrier, thereby forming recess gates 200. Reference numerals 27A and 28A represent a patterned gate polysilicon layer and a patterned gate metal layer, respectively.

As for each of the recess gates 200, a bottom portion of the recess gate 200 is filled into the corresponding recess 25, while an upper portion of the recess gate 200 is protruded upwardly from a surface of the substrate 21. Because of this specific structure of the recess gates 200, the channel length is increased.

In the above gate patterning process for forming the recess gates 200 at the HDP etch apparatus using the ICP or the DPS, the etching of the gate metal layer 28 is carried out in two processes; those are, a main etching process and an over etching process. The main etching process is carried out at the high density plasma (HDP) etch apparatus in which the ICP, the DPS or the ECR is used. At this time, the etch gas uses approximately 10 sccm to approximately 50 sccm of an etch gas selected from a group consisting of BCl₃, a CF-based gas, a NF-based gas, and SF-based gas, approximately 50 sccm to approximately 200 sccm of Cl₂ gas, or a combination thereof.

To make a cross-sectioned etch profile of the individual recess gate 200 perpendicular, the gate patterning process specifically for etching the gate metal layer 28 uses a source power set in a range from approximately 500 W to approximately 2,000 W and a gas selected from a group consisting of O₂, Ar, nitrogen (N₂) helium (He) and a combination thereof. At this time, approximately 1 sccm to approximately 20 sccm of the O₂ gas is used; approximately 1 sccm to approximately 1,090 sccm of the N₂ gas is used; approximately 50 sccm to approximately 200 sccm of the Ar gas is used; and approximately 50 sccm to approximately 20 sccm of the He gas is used.

Also, in the gate patterning process at the HDP etch apparatus using the ECR, microwave power set in a range from approximately 1,000 W to approximately 3,000 W and a gas selected from a group consisting of O₂, Ar, N₂, helium and a combination thereof are used to make a cross-sectioned etch profile of the individual recess gate 200 perpendicular. At this time, approximately 1 sccm to approximately 20 sccm of the O₂ gas is used; approximately 1 sccm to approximately 1,090 sccm of the N₂ gas is used; approximately 50 sccm to approximately 200 sccm of the Ar gas is used; and approximately 50 sccm to approximately 20 sccm of the He gas is used.

After the above main etching process, the gate metal layer 28 is subjected to the over-etching process by using a mixed plasma including Cl₂ gas and N₂ gas or a plasma obtained by adding O₂ gas and He gas to a mixed gas of Cl₂ gas and N₂ gas to prevent the gate insulation layer 26 from being damaged during the over-etching process even if the gate insulation layer 26 is exposed by the over-etching process. Each of the above mentioned plasmas has high etch selectivity with respect to oxide. The Cl₂ gas is flowed in an amount ranging from approximately 20 sccm to approximately 150 sccm, while the N₂ gas is flowed in an amount ranging from approximately 10 sccm to approximately 100 sccm.

During the gate patterning process for forming the recess gates 200, the gate polysilicon layer 27 is etched at the HDP etch apparatus using the ICP, the DPS or the ECR. At this time, a mixed plasma containing HBr gas and O₂ gas is used as an etch gas to selectively etch the gate polysilicon layer 27 without using up the patterned gate metal layer 28A and the gate insulation layer 26. Through this selective etching, both lateral sides of the gate polysilicon layer 27 beneath the patterned gate metal layer 28 are undercut.

In the case that the selective etching of the gate polysiliocn layer 27 is carried out at the HDP etch apparatus using the ICP and the DPS, a source power is set to range from approximately 500 W to approximately 2,000 W and, the HBr gas is flowed in an amount ranging from approximately 50 sccm to approximately 200 sccm and the O₂ gas is flowed in an amount ranging from approximately 2 sccm to approximately 20 sccm.

In the case that the gate polysiliocn layer 27 is etched at the HDP etch apparatus using the ECR, microwave power is set to be in a range from approximately 1,000 W to approximately 3,000 W, and the HBr gas is flowed in an amount ranging from approximately 50 sccm to approximately 200 sccm and the O₂ gas is flowed in an amount ranging from approximately 2 sccm to approximately 20 sccm.

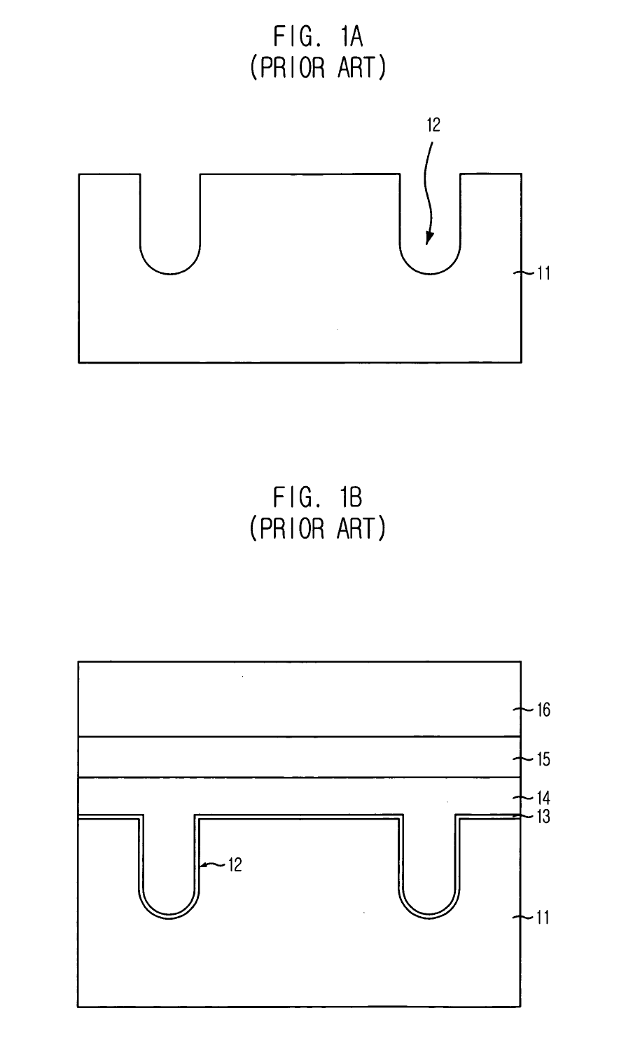

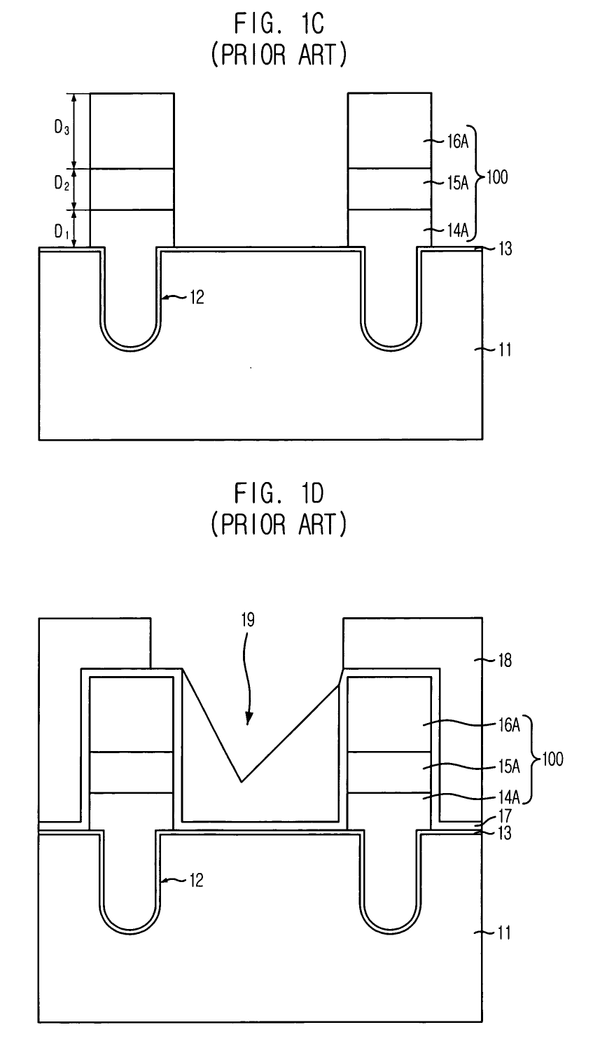

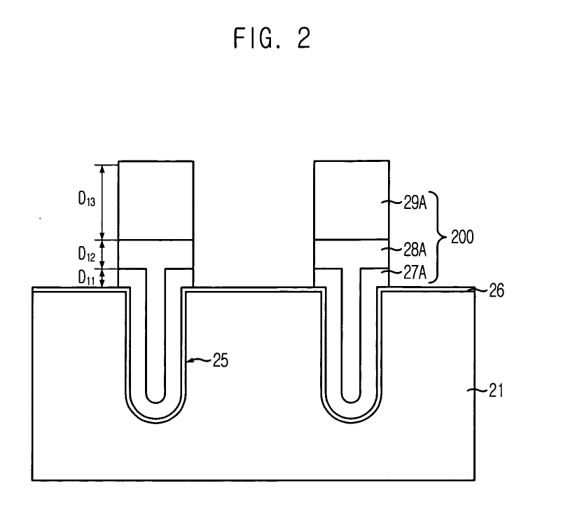

In comparison with the recess gate 100 shown in FIG. 1D, characteristics of the recess gate 200 according to the present invention will be described in detail.

First, as for the thickness of the gate polysilicon layer, the patterned gate polysilicon layer 14A is formed with a thickness of D1 that is enough to fill the recesses 12. However, the patterned gate polysilicon layer 27A is formed with a thickness D11 without filling the recesses 25. Thus, the patterned gate polysilicon layer 27A according to the present invention is thinner than the conventionally formed patterned gate polysilicon layer 14A.

Second, the patterned gate metal layer 15A is formed with a small contact area with the patterned gate polysilicon layer 14A, and thus, the patterned gate metal layer 15A is formed thickly to reduce the line resistance of the recess gate 100. A reference denotation D2 in FIG. 1E expresses the thickness of the patterned gate metal layer 15A. On the contrary, according to the present invention, even though the gate metal layer 28 is formed with a thin thickness D12 but enough to fill the recesses 25, the line resistance of the recess gates 200 can be still reduced. Hence, the thickness D12 of the patterned gate metal layer 28A is less than that D2 of the conventionally formed patterned gate metal layer 15A. Also, it should be noted that a thickness D3 of the conventionally formed gate hard masks 16A is identical to that D13 of the gate hard masks 29A according to the present invention.

As described above, since the patterned gate polysilicon layer and the patterned gate metal layer are formed thinly, the recess gates according to the present invention are free from a void generation in the gate material filled into the recesses. Also, since the overall height of the recess gates is reduced, it is easy to etch a plug isolation oxide layer during an etching process for forming contact holes for forming contact plugs.

FIG. 4 is a cross-sectional view illustrating a method for forming a contact hole in a semiconductor device to which recess gates according to the preferred embodiment of the present invention are applied. Herein, the same reference numerals are used for the same configurations elements described in FIG. 2 and FIGS. 3A to 3E and detailed description of processes for forming such configuration elements will be omitted.

As shown, a gate spacer layer 31 made of silicon nitride is formed over the recess gates 200 and then, an inter-layer insulation layer 32 serving as a plug isolation layer is formed on the gate spacer 31. Then, the inter-layer insulation layer 32 is etched through a self-aligned contact (SAC) etching process to form a contact hole 33 opening a surface of the substrate 21. Although not illustrated, the SAC etching process uses a contact mask as an etch barrier when the inter-layer insulation layer 32 is etched and, the gate spacer layer 31 is etched thereafter.

Particularly, the SAC etching process uses an etch gas that provides high etch selectivity of the inter-layer insulation layer 32 with respect to the gate hard masks 29A and the gate spacer layer 31 both of which are a nitride-based layer. The etch gas is selected from a group of gases containing a high level of carbons inducing a large amount of polymers. That is, the etch gas is one selected from a group consisting of C₂F₆, C₂F₄, C₃F₆, C₃F₈, C₄F₈, C₅F₈, C₅F₁₀ and C₂HF₅.

Also, a hydrogen-containing gas is added to the above mentioned etch gas used for the SAC etching process to increase selectivity of the inter-layer insulation layer 32 with respect to the gate hard masks 29A and the gate spacer layer 31 and increase a window for the SAC etching process for securing reproducibility of the SAC etching process. At this time, the hydrogen containing gas is selected from a group consisting of CHF₃, CH₂F₂, CH₃F, CH₂, CH₄, C₂H₄ and H₂. Also, the hydrogen containing gas can use a family of CₓH_{y}F_{z}, where x≧2, y≧2 and z≧2.

In addition, an inert gas can be added to the mixed gas to prevent an incidence of etch-stop by improving plasma stability and a sputtering effect during the etching of the inter-layer insulation layer 32. At this time, the inert gas is selected from a group consisting of He, Ne, Ar and Ze.

Since the height of the individual recess gate 200 is reduced, the incidence of the etch-stop does not occur during the SAC etching process, thereby preventing generation of defects related to a contact opening.

In accordance with the preferred embodiment, it is possible to improve a refresh characteristic of a semiconductor device including recess gates by being able to reduce the height and line resistance of the recess gates. Also, the reduced height of the recess gate prevents an incidence of defective contact opening caused by the etch-stop phenomenon when contact holes are formed through the SAC etching process. As a result of this effect, it is possible to increase the yield of semiconductor devices.

The present application contains subject matter related to the Korean patent application No. KR 2004-0115061, filed in the Korean Patent Office on Dec. 29, 2004, the entire contents of which being incorporated herein by reference.

While the present invention has been described with respect to certain preferred embodiments, it will be apparent to those skilled in the art that various changes and modifications may be made without departing from the spirit and scope of the invention as defined in the following claims.

What is claimed is:

1. A recess gate of a semiconductor device, comprising:
a substrate;
a recess formed with a predetermined depth in a predetermined portion of the substrate;
a gate insulation layer formed over the substrate;
a gate polysilicon layer formed on the gate insulation layer;
a gate metal layer formed on the gate polysilicon layer and filling the recess; and
a gate hard mask formed on the gate metal layer.

2. The recess gate of claim 1, wherein the gate polysilicon layer has a thickness ranging from approximately 100 Å to approximately 1,000 Å.

3. The recess gate of claim 1, wherein the gate metal layer is selected from a group consisting of tungsten, tungsten silicide, cobalt silicide and titanium silicide.

4. The recess gate of claim 3, wherein the gate metal layer has a thickness ranging from approximately 500 Å to approximately 1,500 Å.

5. The recess gate of claim 1, wherein the recess has a rounded edge.

6. The recess gate of claim 1, wherein the substrate is based on silicon.

7. A method for fabricating a semiconductor device, comprising the steps of:
forming a recess by etching a substrate to a predetermined depth;
forming a gate insulation layer over the substrate;
forming a gate polysilicon layer on the gate insulation layer;
forming a gate metal layer on the gate polysilicon layer such that the gate metal layer fills the recess;
forming a gate hard mask layer on the gate metal layer; and
sequentially etching the gate hard mask layer, the gate metal layer and the gate polysilicon layer to form a recess gate having bottom portion filled into the recess.

8. The method of claim 7, wherein the step of forming the recess includes the steps of:
forming a hard mask polysilicon layer on the substrate;
forming a mask pattern on the hard mask polysilicon layer;
etching the hard mask polysilicon layer by using the mask pattern as an etch barrier;
etching a predetermined portion of the substrate to a predetermined depth by using the hard mask polysilicon layer as an etch barrier, thereby forming the recess; and
performing an additional etching process on the recess to obtain rounded edges of the recess.

9. The method of claim 8, wherein the additional etching process uses a CF/O₂ mixed plasma.

10. The method of claim 8, wherein the step of forming the recess is carried out at an etch apparatus using one of an inductively coupled plasma, a decoupled plasma source, an electron cyclotron resonance, and a magnetically enhanced reactive ion etch by employing an etch gas obtained by mixing Cl₂ gas, O₂ gas, HBr gas and Ar gas.

11. The method of claim 7, wherein the gate polysilicon layer has a thickness ranging from approximately 100 Å to approximately 1,000 Å.

12. The method of claim 7, wherein the gate metal layer is formed by using a material selected from a group consisting of tungsten, tungsten silicide, cobalt silicide, and titanium silicide.

13. The method of claim 12, wherein the gate metal layer has a thickness ranging from approximately 500 Å to approximately 1,500 Å.

14. The method of claim 7, wherein the step of forming the recess gate includes the steps of:
etching the gate hard mask layer;
etching the gate metal layer in two processes including a main etching process and an over-etching process by using the etched gate hard mask layer as an etch barrier; and
etching the gate polysilicon layer.

15. The method of claim 14, wherein the step of forming the recess gate is carried out at an etch apparatus using one of an inductively coupled plasma, a decoupled plasma source, an electron cyclotron resonance, and a magnetically enhanced reactive ion etch.

16. The method of claim 14, wherein the over-etching process with respect to the gate metal layer is carried out by using one of a Cl₂/N₂ mixed plasma and a plasma obtained by adding O₂ gas and He gas to a mixed gas of Cl₂ and N₂.

17. The method of claim 16, wherein the Cl₂ gas is flowed in an amount ranging from approximately 20 sccm to approximately 150 sccm and the N₂ gas is flowed in an amount ranging from approximately 10 sccm to approximately 100 sccm.
